(19) United States
(12) Patent Application Publication
(10) Pub. No.: US 2015/0027765 A1
(43) Pub. Date: Jan. 29, 2015

(54) NICKEL POWDER FOR INTERNAL ELECTRODES, MULTILAYER CERAMIC CAPACITOR INCLUDING THE SAME, AND CIRCUIT BOARD HAVING ELECTRONIC COMPONENT MOUNTED THEREON

(71) Applicant: SAMSUNG ELECTRO-MECHANICS CO., LTD., Suwon (KR)

(72) Inventors: Gun Woo KIM, Suwon (KR); Hyo Sub KIM, Suwon (KR); Jeong Ryeol KIM, Suwon (KR); Chang Hoon KIM, Suwon (KR); Doo Young KIM, Suwon (KR); Dong Hoon KIM, Suwon (KR)

(73) Assignee: SAMSUNG ELECTRO-MECHANICS CO., LTD., Suwon (KR)

(21) Appl. No.: 14/085,018

(22) Filed: Nov. 20, 2013

(30) Foreign Application Priority Data
Jul. 23, 2013 (KR) 10-2013-0086680

(51) Int. Cl. H01G 4/008; H05K 1/18; H01G 4/30

(52) U.S. Cl. CPC H01G 4/008; H01G 4/30; H05K 1/181
USPC 174/260; 361/301.4; 420/441; 428/546

(57) ABSTRACT

There is provided a nickel powder for internal electrodes satisfying the following equation: 0.8≦b*D*ρ/6≦1.0 wherein a specific surface area of the nickel powder is defined as b, an average particle size of the nickel powder is defined as D, and a density of the nickel powder is defined as ρ.

### CROSS-REFERENCE TO RELATED APPLICATION

This application claims the benefit of Korean Patent Application No. 10-2013-0086680 filed on Jul. 23, 2013, with the Korean Intellectual Property Office, the disclosure of which is incorporated herein by reference.

### BACKGROUND OF THE INVENTION

1. Field of the Invention

The present invention relates to a nickel powder for internal electrodes, and more particularly, to a nickel powder for internal electrodes having high dispersibility, large crystallite size, and high density, a multilayer ceramic capacitor including the same, and a circuit board having an electronic component mounted thereon.

2. Description of the Related Art

As electronic devices have rapidly progressed to be relatively small and highly functional, a trend in which a multilayer ceramic capacitor, a key passive component in electronic devices, also has high capacitance and ultra thinness has emerged.

In general, in multilayer ceramic electronic components, internal electrodes are printed on ceramic dielectric sheets, and the ceramic dielectric sheets having the internal electrodes printed thereon are stacked and sintered, and external electrodes are then formed on a multilayer body.

Since the internal electrode printed on the ceramic dielectric sheet has a lower sintering initiation temperature than the ceramic dielectric sheet such that sintering thereof may be initiated at a temperature lower than the sintering temperature of the ceramic dielectric sheet, the internal electrode may be excessively sintered to be agglomerated in a state in which metal components are unevenly distributed. After sintering, the internal electrodes may have disconnected portions, such that connectivity of the internal electrodes may be significantly deteriorated, and therefore, the capacitance of the multilayer ceramic capacitor may be reduced.

Therefore, in order to increase the capacitance of the multilayer ceramic capacitor, it is required to improve the connectivity of the internal electrodes and to develop a metal powder capable of increasing the connectivity of the internal electrodes.

### RELATED ART DOCUMENT

(Patent Document 1) Korean Patent Laid-Open Publication No. 10-2011-0089630

### SUMMARY OF THE INVENTION

An aspect of the present invention provides a nickel powder for internal electrodes having high dispersibility, large crystallite size, and high density, a multilayer ceramic capacitor including the same, and a circuit board having an electronic component mounted thereon.

According to an aspect of the present invention, there is provided a nickel powder for internal electrodes satisfying the following equation: 0.8≦b*D*ρ/6≦1.0 wherein a specific surface area of the nickel powder is defined as b, an average particle size of the nickel powder is defined as D, and a density of the nickel powder is defined as ρ.

The average particle size of the nickel powder may be 50 nm to 350 nm.

A crystallite size of the nickel powder may be 55 nm to 100 nm.

An average number of crystallites per one particle of the nickel powder may be 1 to 8.

The density of the nickel powder may be 8.5 g/cm³ or greater.

A content of impurities in the nickel powder may be 500 ppm or less.

According to another aspect of the present invention, there is provided a multilayer ceramic capacitor including: a ceramic body including dielectric layers; a plurality of internal electrodes formed in the ceramic body, having the dielectric layers interposed therebetween, and including a nickel powder; and external electrodes formed on external surfaces of the ceramic body and electrically connected to the internal electrodes, wherein when a specific surface area of the nickel powder is defined as b, an average particle size of the nickel powder is defined as D, and a density of the nickel powder is defined as ρ, the nickel powder satisfies the following equation: 0.8≦b*D*ρ/6≦1.0.

The average particle size of the nickel powder may be 50 nm to 350 nm.

A crystallite size of the nickel powder may be 55 nm to 100 nm.

An average number of crystallites per one particle of the nickel powder may be 1 to 8.

The density of the nickel powder may be 8.5 g/cm³ or greater.

A content of impurities in the nickel powder may be 500 ppm or less.

According to another aspect of the present invention, there is provided a circuit board having an electronic component mounted thereon, the circuit board including: a printed circuit board having first and second electrode pads disposed thereon; and a multilayer ceramic capacitor mounted on the printed circuit board, wherein the multilayer ceramic capacitor includes: a ceramic body including dielectric layers; a plurality of internal electrodes formed in the ceramic body, having the dielectric layers interposed therebetween, and including a nickel powder; and external electrodes formed on external surfaces of the ceramic body and electrically connected to the internal electrodes, and when a specific surface area of the nickel powder is defined as b, an average particle size of the nickel powder is defined as D, and a density of the nickel powder is defined as ρ, the nickel powder satisfies the following equation: 0.8≦b*D*ρ/6≦1.0.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B show transmission electron microscopy (TEM) images of a nickel powder for internal electrodes according to an embodiment of the present invention;

FIG. 2 shows a transmission electron microscopy (TEM) image of a nickel powder for internal electrodes including a plurality of crystallites according to an embodiment of the present invention;

FIG. 3 shows an image of particles of a nickel powder for internal electrodes including a plurality of crystallites according to an embodiment of the present invention;

FIG. 4 is a perspective view schematically showing a multilayer ceramic capacitor according to an embodiment of the present invention;

FIG. 5 is a cross-sectional view of line A-A′ of FIG. 4; and

FIG. 6 is a perspective view schematically showing a circuit board having an electronic component mounted thereon according to an embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

### Nickel Powder for Internal Electrodes

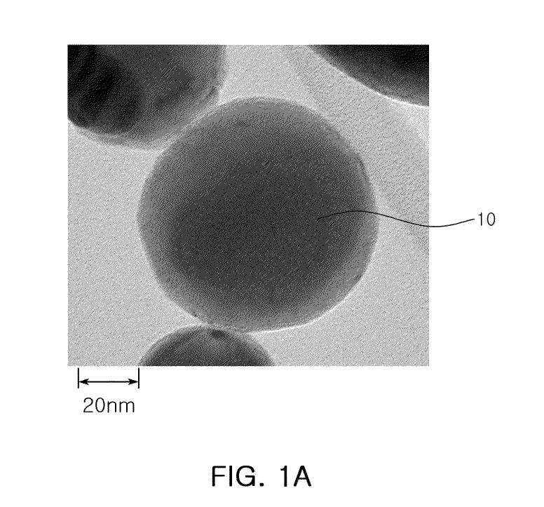

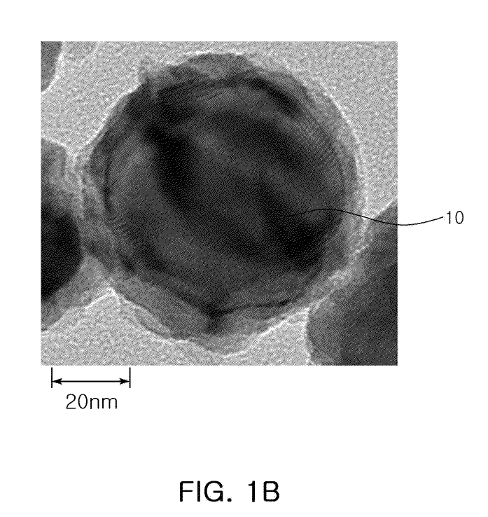

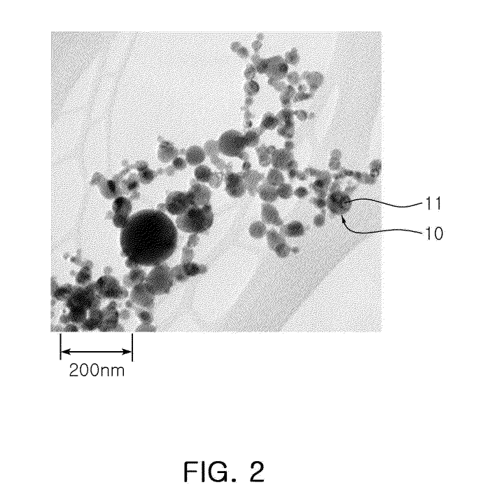

FIGS. 1A and 1B show transmission electron microscopy (TEM) images of a nickel powder for internal electrodes according to an embodiment of the present invention, and FIG. 2 shows a transmission electron microscopy (TEM) image of a nickel powder for internal electrodes including a plurality of crystallites according to an embodiment of the present invention.

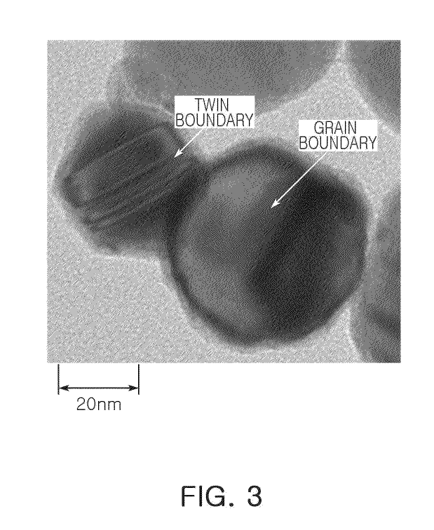

FIG. 3 shows an image of particles of a nickel powder for internal electrodes including a plurality of crystallites according to an embodiment of the present invention.

Referring to FIGS. 1A and 1B, a nickel powder 10 for internal electrodes according to an embodiment of the invention may have a predetermined level of surface roughness. More specifically, when a specific surface area of the nickel powder is defined as b, an average particle size of the nickel powder is defined as D, and a density of the nickel powder is defined as ρ, an χ value of b*D*ρ/6 may satisfy the following equation: 0.8≦b*D*ρ/6≦1.0.

Since a morphology of the nickel powder whose surface area is significantly decreased is a spherical shape, the X value of the independent nickel particle may not be greater than 1.0. In the case in which the measured χ value is greater than 1.0, the nickel powder for internal electrodes may be agglomerated. At the time of preparing the nickel powder as a paste for internal electrodes, the agglomeration of the nickel powder may deteriorate a filling rate of the paste, and cause the surface thereof to be inappropriately rough. In addition, in the case in which the χ value is less than 0.8, the surface roughness is high. In this case, when the paste for internal electrodes is prepared, excessively large amounts of a dispersant and a binder based on the nickel powder may be needed in order to obtain surface stability of the nickel powder. In the case in which the amounts of the dispersant and the binder are increased in the paste, a large amount of gas may be generated at the time of sintering a green chip to cause defects such as an explosion of the chip or the like. In addition, in the case in which the nickel particle surface is excessively rough, the nickel particles may be spaced apart from each other, such that the filling rate of the nickel powder in the paste for internal electrodes may be deteriorated.

In other words, in the case of the nickel powder 10 satisfying the χ value of 0.8 to 1.0 as described in the embodiment of the invention, adsorption with the dispersant may be increased, and dispersibility of the particles may be excellent. In particular, in the case of manufacturing the internal electrodes of the multilayer ceramic capacitor using the nickel powder 10, sufficient amounts of dispersant and resin may be adsorbed on the surface of the particles forming the nickel powder, the filling rate of the particles may be excellent and the manufactured internal electrodes may have improved connectivity.

The nickel powder having the χ value of 0.8 to 1.0 may be prepared by controlling the formation of an oxide film of the nickel particle.

The specific surface area (b) of the nickel powder may be 2 m²/g to 15 m²/g, but the invention is not limited thereto.

In addition, the nickel powder according to the embodiment of the invention may be prepared by vapor-phase synthesis using plasma, but the invention is not limited thereto, and a gas for forming the oxide film (hereinafter, referred to as a film forming gas) may be introduced in a temperature section in which the growth of the nickel particle formed by physical vapor deposition (PVD) is finished, such that the oxide film may be formed on the surface of the particle. Here, the introduced gas may be pure oxygen.

In particular, even when the same film forming gas is introduced, the surface roughness of the particle may be varied depending on temperatures at which the gas is introduced. More specifically, as the film forming gas is introduced at higher temperatures, the surface roughness of the particle may be increased.

In order to obtain the χ value of 0.8 to 1.0, the film forming gas may be introduced at a temperature of 50° C. to 300° C.

In addition, referring to FIGS. 2 and 3, the nickel powder 10 for internal electrodes according to the embodiment of the invention may have an average particle size of 55 nm to 350 nm, and crystallites 11 included therein may have a size of 55 nm to 100 nm.

The crystallinity of the particle may be determined by the size of the crystallites, crystallites being single crystals within the particle, one particle being formed of a plurality of crystallites.

A size (L) of the crystallite may be measured through x-ray diffraction (XRD) analysis, and may be expressed as follows.

L=Kλ/(β cos θ)

(K: integer (0.9), λ: wavelength, β: a full width at half maximum of peak, θ: refraction angle)

The nickel powder 10 according to the embodiment of the invention may be prepared by the vapor-phase synthesis using the plasma, and have the X value in the above range allowing for improved dispersibility, less impurities (500 ppm or less), and large crystallite size (55 nm or more), resulting in less particle defects to have a density close to a theoretical density (8.5 g/cm³ or more).

The nickel powder 10 according to the embodiment of the invention has the excellent filling rate between the particles to improve the connectivity of the internal electrodes.

### Multilayer Ceramic Capacitor

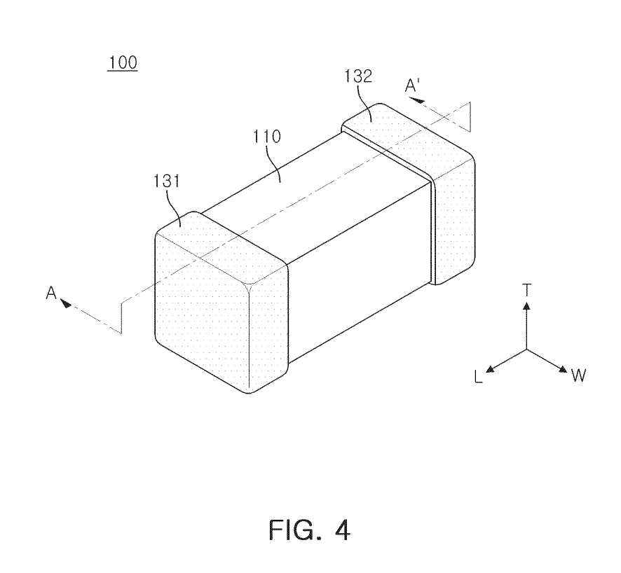

FIG. 4 is a schematic perspective view showing a multilayer ceramic capacitor according to an embodiment of the present invention.

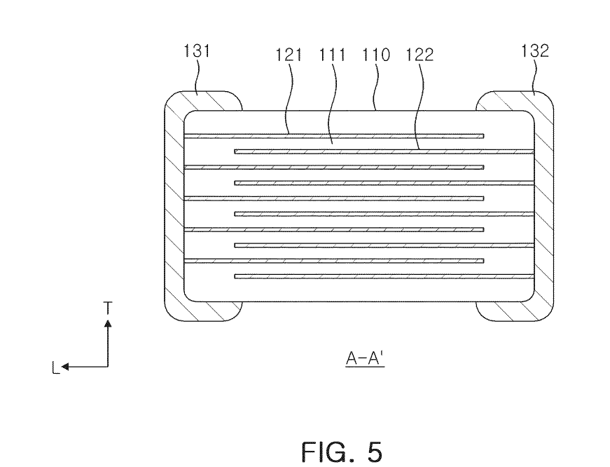

FIG. 5 is a cross-sectional view of line A-A′ of FIG. 4.

Referring to FIG. 4, the multilayer ceramic capacitor according to the embodiment of the invention may include a ceramic body 110 and first and second external electrodes 131 and 132.

According to the embodiment of the invention, a T-direction may refer to a thickness direction of the ceramic body and a direction in which the internal electrodes are stacked, having the dielectric layer interposed therebetween, and an L-direction may refer to a length direction of the ceramic body, and a W-direction may refer to a width direction of the ceramic body.

The length of the ceramic body 110 in the length direction may be greater than that of the ceramic body 110 in the width direction or in the thickness direction.

In the embodiment of the invention, the ceramic body 110 may substantially have a hexahedral shape, but the shape of the ceramic body 110 is not particularly limited. Due to sintering shrinkage of ceramic powder at the time of sintering a chip, a difference in thickness depending on the presence of internal electrode patterns, and abrasion of edge portions of the ceramic body, the ceramic body 110 may not have a complete hexahedral shape, but may substantially have a shape similar to a hexahedron.

Referring to FIG. 5, the ceramic body 110 may include a plurality of dielectric layers 111 and a plurality of internal electrodes 121 and 122 alternately exposed through both end surfaces of the ceramic body 110, having the dielectric layers 111 interposed therebetween.

According to the embodiment of the invention, the plurality of dielectric layers 111 forming the ceramic body 110 are in a sintered state, and adjacent dielectric layers may be integrated such that boundaries therebetween may not be readily apparent.

The first and second internal electrodes 121 and 122, a pair of electrodes having opposite polarities, may be alternately exposed through both end surfaces of the ceramic body by printing a conductive paste including a conductive metal on the dielectric layers 111 at a predetermined thickness, and may be insulated from each other by the dielectric layer 111 disposed therebetween.

That is, the first and second internal electrodes 121 and 122 may be electrically connected to the first and second external electrodes 131 and 132, respectively, through portions thereof alternately exposed through both end surfaces of the ceramic body 110.

Therefore, when voltage is applied to the first and second external electrodes 131 and 132, electric charges are accumulated between the first and second internal electrodes 121 and 122 facing each other. Here, capacitance of the multilayer ceramic capacitor 100 is in proportion to an area of a region in which the first and second internal electrodes 121 and 122 are overlapped with each other.

In addition, the conductive metal included in the first and second internal electrodes 121 and 122 may be nickel (Ni), copper (Cu), palladium (Pd), or alloys thereof, but the invention is not limited thereto.

The conductive metal may be provided in the form of the nickel powder 10 for internal electrodes according to the above-described embodiment of the invention.

That is, with regard to the nickel powder included in the internal electrodes of the multilayer ceramic capacitor according to the embodiment of the invention, when a specific surface area of the nickel powder is defined as b, an average particle size of the nickel powder is defined as D, and a density of the nickel powder is defined as ρ, an χ value of b*D*ρ/6 may satisfy the following equation: 0.8≦b*D*ρ/6≦1.0.

In addition, the average particle size of the nickel powder may be 50 nm to 350 nm, and the crystallite size of the nickel powder may be 55 nm to 100 nm.

In addition, an average number of crystallites per one particle in the nickel powder may be 1 to 8, a density of the nickel powder may be 8.5 g/cm³ or greater, and a content of impurities in the nickel powder may be 500 ppm or less.

Further, the dielectric layer 111 may include a ceramic material having high permittivity, for example, a barium titanate (BaTiO₃) based powder or a strontium titanate (SrTiO₃) based powder. However, the invention is not limited thereto.

The first external electrode 131 may be electrically connected to the first internal electrode 121, and the second external electrode 132 may be electrically connected to the second internal electrode 122.

### Circuit Board Having Electronic Component Mounted Thereon

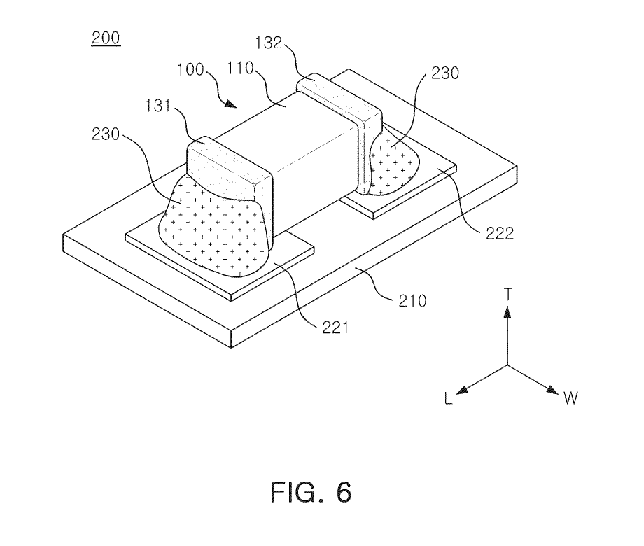

FIG. 6 is a perspective view showing a circuit board having an electronic component mounted thereon according to another embodiment of the invention.

Referring to FIG. 6, a circuit board 200 having an electronic component mounted thereon according to the present embodiment may include a printed circuit board 210 having first and second electrode pads 221 and 222 disposed thereon; and a multilayer ceramic capacitor 100 mounted on the printed circuit board.

Here, the multilayer ceramic capacitor 100 may be electrically connected to the printed circuit board 210 by a solder 230 in a state in which the first and second external electrodes 131 and 132 are positioned to contact the first and second electrode pads 221 and 222, respectively.

An overlapped description of the above-described multilayer ceramic capacitor with the description of the circuit board having the multilayer ceramic capacitor mounted thereon will be omitted.

### INVENTIVE EXAMPLE

A nickel powder for internal electrodes of a multilayer ceramic capacitor according to Inventive Example was synthesized by the following processes.

After RF-plasma (plasma formed by changing a current direction in a RF cycle) ignition, a nickel metal raw material having a size of about 10 um was put into a reactor. After the nickel metal raw material was heated and evaporated under an inert gas atmosphere, the evaporated nickel metal raw material was condensed to form a nickel powder.

Ignition conditions of RF-plasma for synthesizing the nickel powder are shown in the following Table 1.

TABLE 1

| | |
|---|---|
| Power | 60 kW |
| Central Gas | 301/min (Ar) |
| Sheath Gas | 1001/min (Ar + H²) |
| Quenching Gas | 15001/min (Ar) |
| Feeding Rate | 10 g/min |

A temperature in a quenching zone of a device for controlling particle growth is an important factor for crystallinity of particles, and the size of crystallites in a particle grown at each of three temperature profiles of 100° C., 200° C., and 300° C. in the quenching zone obtained by controlling a degree of the quenching gas was measured by x-ray diffraction (XRD) analysis.

Differences in crystallite size analyzed according to the temperatures in the quenching zone are shown in the following Table 2.

TABLE 2

| Particle | Temperature in Quenching Zone | Crystallite Size |
|---|---|---|
| A | 100° C. | 25 nm |
| B | 200° C. | 32 nm |
| C | 300° C. | 58 nm |

Scanning electron microscopy (SEM) images of FIGS. 2A and 2B illustrate the synthesized nickel powder in a state in which the temperature in the quenching zone was 300° C., and FIG. 3 illustrates a transmission electron microscopy (TEM) image of particles of the same powder.

In addition, FIGS. 1A and 1B illustrate the particle formed of one crystallite, and FIG. 3 illustrates the particle formed of a plurality of crystallites including boundaries (a twin boundary and a grain boundary).

Physical properties of the nickel powder A, B, and C synthesized depending on respective temperatures of the quenching zone are shown in the following Table 3.

TABLE 3

| | A | B | C |
|---|---|---|---|
| Temperature in | 100° C. | 200° C. | 300° C. |
| Quenching | | | |
| Zone | | | |
| Crystallite Size | 25 nm | 32 nm | 58 nm |
| (Dc) | | | |
| Carbon Content | 139 ppm | 223 ppm | 180 ppm |
| Density | 8.31 g/cm³ | 8.48 g/cm³ | 8.72 g/cm³ |
| Average | 78 nm (Rmax | 80 nm (Rmax | 81 nm (Rmax 310 nm) |
| Particle | 297 nm) | 320 nm) | |
| diameter (Da) | | | |
| Da/Dc | 3.12 | 2.50 | 1.40 |

When a crystallite size of the particle measured by the XRD is defined as Dc and an average particle diameter measured using the SEM image is defined as Da, (Da/Dc)³ indicates an average number of crystallites per one particle.

That is, it may be appreciated that the particle A is formed of about 30.4 (3.12³) crystallites, the particle B is formed of about 15.6 (2.50³) crystallites, and the particle C is formed of about 2.7 (1.40³) crystallites.

The powder was added to ethyl cellulose as a binder and a terpineol solvent, thereby preparing a paste for internal electrodes of a multilayer ceramic capacitor. After the paste was thinly applied to a film and dried in a state in which inner bubbles were removed under vacuum conditions, a density of the paste dried film was measured and compared with a theoretical density value.

In addition, after a barium titanate-based ceramic powder was added to a polyvinylbutyral-based polymer as a binder and an organic solvent such as ethanol or the like, a wet-mixing method was performed to prepare a ceramic slurry, and the ceramic slurry was used to form ceramic green sheets using a doctor blade method. Then, the conductive paste was printed by a screen printing method and dried to form internal electrodes.

Next, the ceramic green sheets having the conductive paste films printed thereon were stacked while allowing portions thereof through which the conductive paste films are exposed to be alternately disposed, compressed to be integrated with each other, and cut to obtain a green chip having a predetermined size.

Then, a debinding process was performed by a heat-treatment at 250° C. under a nitrogen atmosphere, and a sintering process was performed at 1000° C. to 1200° C. under a reducing atmosphere, thereby obtaining a sintered chip, and the connectivity of the internal electrode of the sintered chip was measured.

Properties of the paste and the sintered chip, including the particles synthesized according to the temperatures in the quenching zone applied thereto, are shown in the following Table 4.

TABLE 4

| | | Electrode |
|---|---|---|
| | Density of Paste Dried Film/ | Connectivity of |
| Particle | Density of Theoretical Dried Film | Sintered Chip |
| A | 93% | 90% |
| B | 94% | 91% |
| C | 98% | 96% |

Crystalline particles having large crystallite size and including a small number of crystallites therein may have high density due to a reduction of defects in the particles, resulting in an increase in the density of the paste dried film at the time of preparing the paste. In addition, the electrode connectivity of the sintered chip may be improved due to the increase in the density of the paste dried film.

Further, the following Table 5 shows data values of oxygen content, average particle size (D), density (ρ), specific surface area (b, measured by a BET method) and χ (i.e., b*D*ρ/6) in nickel particles formed depending on temperatures at which film forming gas was introduced. In this case, pure oxygen was used as the film forming gas, and was introduced to satisfy conditions of 0.11 pm and 1 wt %/Ni.

TABLE 5

| | Sample | | | | |
|---|---|---|---|---|---|
| | 1 | 2 | 3 | 4 | 5 |
| Temperatures at the | 50 | 100 | 150 | 200 | 250 |
| time of Introducing | | | | | |
| Film Forming Gas | | | | | |
| (° C.) | | | | | |
| Oxygen Content | 0.62 | 0.97 | 0.98 | 1.02 | 0.99 |
| (wt %) | | | | | |
| Average Particle Size | 94 | 92 | 95 | 102 | 98 |
| (nm) | | | | | |
| Density (g/cm³) | 8.7 | 8.5 | 8.5 | 8.4 | 8.5 |
| Specific Surface Area | 6.33 | 6.43 | 6.73 | 6.94 | 6.74 |
| (m²/g) | | | | | |
| χ | 0.863 | 0.838 | 0.906 | 0.991 | 0.936 |

As shown in Table 5 above, all χ values at temperatures from 50° C. to 250° C. are in the range of 0.8 to 1.0. In particular, when the film forming gas was introduced at 150° C. to 200° C., the χ value ranged from 0.9 to 1.0, and the nickel particle had significantly superior dispersibility.

In addition, when the film forming gas was introduced at 100° C. to 250° C., the oxygen content in the particle was similar to an initially introduced oxygen concentration, so that it was easy to control the oxygen content. Meanwhile, when the film forming gas was introduced at a temperature above 250° C., connections between the nickel particles resulted in a reduction of the specific surface area value.

Therefore, the nickel powders of samples 2 to 4 are compared with each other in terms of an adsorption amount with respect to a dispersant, and the comparison results are shown in the following Table 6.

TABLE 6

| | Density After Adsorption of Dispersant/ |
|---|---|
| Sample | Density Before Adsorption of Dispersant |
| 2 | 0.97 |
| 3 | 0.95 |
| 4 | 0.90 |

It may be appreciated with reference to Table 6 above that the ratios of ‘density after adsorption of dispersant/density before adsorption of dispersant’ were decreased from sample 2 to sample 4, and dispersibility was improved.

In addition, with respect to samples 2 to 4, the ratios of ‘density of paste dried film/density of theoretical dried film’ were measured by the same method as described above with respect to particles A to C and the electrode connectivity of the sintered chips was measured, and the comparison results thereof are shown in the following Table 7.

TABLE 7

| | Density of Paste Dried Film/ | Electrode Connectivity of |
|---|---|---|
| Sample | Density of Theoretical Dried Film | Sintered Chip |
| 2 | 92% | 91% |
| 3 | 94% | 93% |
| 4 | 97% | 96% |

As the χ value was increased, the dispersant was easily adsorbed, such that the dispersant and the resin were adsorbed in sufficient amounts. Therefore, a filling effect between the particles was improved, resulting in an increase in the density of the paste dried film at the time of preparing the paste. In addition, the electrode connectivity of the sintered chip was improved due to the increase in the density of the paste dried film.

As set forth above, according to embodiments of the invention, a nickel powder for internal electrodes having high dispersibility, large crystallite size, and high density, a multilayer ceramic capacitor including the same, and a circuit board having an electronic component mounted thereon may be provided.

While the present invention has been shown and described in connection with the embodiments, it will be apparent to those skilled in the art that modifications and variations can be made without departing from the spirit and scope of the invention as defined by the appended claims.

What is claimed is:

1. A nickel powder for internal electrodes satisfying the following equation: 0.8≦b*D*ρ/6≦1.0 wherein a specific surface area of the nickel powder is defined as b, an average particle size of the nickel powder is defined as D, and a density of the nickel powder is defined as ρ.

2. The nickel powder for internal electrodes of claim 1, wherein the average particle size of the nickel powder is 50 nm to 350 nm.

3. The nickel powder for internal electrodes of claim 1, wherein a crystallite size of the nickel powder is 55 nm to 100 nm.

4. The nickel powder for internal electrodes of claim 1, wherein an average number of crystallites per one particle of the nickel powder is 1 to 8.

5. The nickel powder for internal electrodes of claim 1, wherein the density of the nickel powder is 8.5 g/cm³ or greater.

6. The nickel powder for internal electrodes of claim 1, wherein a content of impurities in the nickel powder is 500 ppm or less.

7. A multilayer ceramic capacitor comprising:
a ceramic body including dielectric layers;
a plurality of internal electrodes formed in the ceramic body, having the dielectric layers interposed therebetween, and including a nickel powder; and
external electrodes formed on external surfaces of the ceramic body and electrically connected to the internal electrodes,
wherein when a specific surface area of the nickel powder is defined as b, an average particle size of the nickel powder is defined as D, and a density of the nickel powder is defined as ρ, the nickel powder satisfies the following equation: 0.8≦b*D*ρ/6≦1.0.

8. The multilayer ceramic capacitor of claim 7, wherein the average particle size of the nickel powder is 50 nm to 350 nm.

9. The multilayer ceramic capacitor of claim 7, wherein a crystallite size of the nickel powder is 55 nm to 100 nm.

10. The multilayer ceramic capacitor of claim 7, wherein an average number of crystallites per one particle of the nickel powder is 1 to 8.

11. The multilayer ceramic capacitor of claim 7, wherein the density of the nickel powder is 8.5 g/cm³ or greater.

12. The multilayer ceramic capacitor of claim 7, wherein a content of impurities in the nickel powder is 500 ppm or less.

13. A circuit board having an electronic component mounted thereon, the circuit board comprising:
a printed circuit board having first and second electrode pads disposed thereon; and
a multilayer ceramic capacitor mounted on the printed circuit board,
wherein the multilayer ceramic capacitor includes:
a ceramic body including dielectric layers;
a plurality of internal electrodes formed in the ceramic body, having the dielectric layers interposed therebetween, and including a nickel powder; and
external electrodes formed on external surfaces of the ceramic body and electrically connected to the internal electrodes, and
when a specific surface area of the nickel powder is defined as b, an average particle size of the nickel powder is defined as D, and a density of the nickel powder is defined as ρ, the nickel powder satisfies the following equation: 0.8≦b*D*ρ/6≦1.0.
